(19) United States
(12) Patent Application Publication
(10) Pub. No.: US 2024/0377218 A1
(43) Pub. Date: Nov. 14, 2024

(54) SYSTEM AND METHOD FOR GENERATING MAGNETISM DATA

(71) Applicant: HERE Global B.V., Eindhoven (NL)

(72) Inventors: Abhishek PANDEY, Dwarka New Delhi (IN); Dev SAVLA, Mumbai (IN); Sachin INGLE, Mumbai (IN); Soumyadip MAJUMDER, West Bengal (IN); Senjuti SEN, Chicago, IL (US)

(21) Appl. No.: 18/196,264

(22) Filed: May 11, 2023

(51) Int. Cl. G01C 21/00; G06N 3/08

(52) U.S. Cl. CPC G01C 21/3837; G06N 3/08

(57) ABSTRACT

A system for generating magnetism data for a measurement unit is disclosed. The system is configured to obtain a set of measurement unit attributes and location information associated with the measurement unit. The set of measurement unit attributes may comprise a first magnetism data for the measurement unit. The system is configured to identify a plurality of reference magnetism sources in proximity of the measurement unit, based on the location information, and obtain reference magnetism data from the plurality of reference magnetism sources. The system is configured to generate second magnetism data for the measurement unit, based on the first magnetism data, the reference magnetism data, and a trained machine-learning based computational network.

### TECHNOLOGICAL FIELD

The present disclosure generally relates to measurement units, and more particularly relates to generating accurate magnetism data of geographical regions for measurement units.

### BACKGROUND

A mobile device may be equipped with a measurement unit to measure certain inertial attributes relating to motion of the mobile device. In an example, the measurement unit may be an electronic device that measures and reports a specific force, angular rate, and/or orientation of the mobile device. Examples of the mobile device may include, but are not limited to, smart phones, personal digital assistants (PDAs), navigational devices, gaming devices, notebooks, handheld devices, tablets, fitness tracking devices, and netbook.

The measurement unit may operate by detecting linear acceleration using one or more accelerometers, rotational or angular rate using one or more gyroscopes, and heading reference or orientation using a magnetometer. In this regard, the measurement unit may contain an accelerometer, a gyroscope and a magnetometer per axis for each of three principal axes, such as pitch, roll and yaw. However, the measurement units are prone to errors that may accumulate over time resulting in highly inaccurate and unreliable outputs. The errors in measurement units may arise due to, for example, high dependency on magnetometers, low grade of magnetometers, magnetic bias, and external or internal disturbance.

Typically, high-grade magnetometers are costly and fusion of the magnetometers with other sensors such as, the accelerometer and the gyroscope of the measurement unit may further increase the cost of the measurement unit. In addition, due to error in output of magnetometer, the readings of the other sensors of the measurement unit may be inaccurate and have gaps. As a result, the output of the measurement unit may be unreliable. In certain cases, the inaccurate measurements from the measurement unit may affect navigation related operations. Owing to errors in measurements, the navigation related operations may not be performed accurately.

Therefore, there is a need to address the drawbacks of magnetometers in measurement units, specifically, for measurement units used in navigational devices for provision of accurate navigation services.

### BRIEF SUMMARY OF SOME EXAMPLE EMBODIMENTS

In modern-day navigation, it becomes critical to depict information pertaining to navigation services with accuracy, clarity and precision. The information pertaining to navigation services may include, but are not limited to, acceleration, speed, rotational or angular rate, heading or orientation, navigation instructions, and time. For example, a measurement unit installed within a mobile device may be configured to measure force, acceleration, speed, angular rate, and orientation of the device. In particular, the measurement unit may include a magnetometer for measuring orientation of the mobile device. Magnetometer reading may be used to determine direction or orientation information or heading of the mobile device, for example, relative to Earth's true north. The heading or orientation information may be provided for user knowledge or for generation or update of navigation instructions generated by a navigational application or device. In certain cases, the magnetometer readings may also affect readings of other sensors in the measurement unit.

A magnetometer obtains a measure of a magnetic field that is present in a geographical region using magnetic sensors. Navigational devices, such as navigation device of an autonomous vehicle requires precise measurements of positioning and rectification of orientation of the vehicle for reliable navigation. To this end, there may be high dependency on magnetometer for accurately measuring orientation or heading of the vehicle. In an example, the magnetometer reading may also be required to assess impact of Earth's magnetism at certain geographical region on gyroscope and accelerometer and correct the final output of the gyroscope and the accelerometer. The magnetic field of the earth may be different for different geographical regions. Moreover, magnetic deviation in the magnetic field of a geographical region may be caused due to movement of earth's magnetic poles.

However, magnetometers are sensitive to their environment. Particularly, the magnetometers induce magnetic bias in its measurements or readings. The magnetic bias may be caused due to, for example, hard iron bias caused by magnetized material inside the magnetometers, or the measurement unit and soft iron bias caused by interaction between variation in magnetic field of earth and materials inside a magnetometer. Moreover, mounting of chip-based magnetometer on a board, such as a board of the measurement unit is critical. Further, field effects of transformers or relays in the measurement unit due to low voltage and low current in a circuit may create magnetic field sufficient enough to disturb the readings of the magnetometer.

Due to external interference from environment, magnetic bias and/or internal disturbances due to magnetic fields, the magnetometer readings may not be precise. Moreover, the magnetometer readings may have high drift over time. Owing to inaccurate readings of the magnetometers, sensor fusion of magnetometer with other sensors, such as accelerometer and gyroscope in the measurement unit may also generate inaccurate readings.

Accelerometers work on a principle that gravitational force is always constant in a direction towards the center of the earth. However, a yaw axis is perpendicular to gravitational force. A movement of the body around the yaw axis, i.e., yaw rotation, indicates change in orientation or heading of the body. Therefore, if roll rotation around a roll axis and pitch rotation around a pitch axis are kept same while yaw angle is changed then accelerometer may fail to measure difference in acceleration. In other words, the accelerometer may fail to measure change in acceleration when there is a change in yaw rotation or yaw angle only and may measure acceleration as a constant value. In such a case, real-time and accurate magnetometer reading may be required for correction of accelerometer reading. For example, based on the magnetometer readings indicating direction or orientation, the movement of the body around the yaw axis or the yaw angle may be corrected. Further, based on the corrected yaw angle, the accelerometer may determine corrected acceleration information. However, conventional magnetometers may fail to provide such precise magnetism reading in real time, thereby, affecting navigation operations.

In order to solve the foregoing problem, the present disclosure may provide a system, a method and a computer programmable product that generates accurate magnetism data for a measurement unit. The system and the method provide techniques for determining movement of earth's magnetic poles and deviation in magnetic field at a particular geographical region. The techniques disclosed in the present disclosure enable determination of accurate magnetic field using a machine learning-based computational network. In this manner, the techniques disclosed in the present disclosure removes dependency of measurement units, such as inertial measurement units, on magnetometers. Due to accurate magnetometer readings generated by the machine-learning based computational network, magnetometers, particularly, high-grade magnetometers, may not have to be fused with the hardware of the measurement unit. This may substantially reduce the cost of the measurement unit. The systems and methods provide techniques for correction and enhancement of readings of sensors, such as accelerometers and gyroscope of the measurement unit.

The system and the method disclose generation of a machine-learning based computational network based on historical magnetism readings and/or crowd sourced magnetism readings. In particular, the machine-learning based computational network may generate accurate magnetism data for a geographical region based on the historical magnetism readings, crowd sourced magnetism readings and measurement unit attributes relating to the measurement unit. The generated magnetism data and/or historical magnetism data of the geographical region may be validated based on reference magnetism data from earth's reference magnetism sources. The updated magnetism data may be used to assess an impact of the earth's magnetism at certain location on a gyroscope and an accelerometer of the measurement unit and correct a final output of the gyroscope and the accelerometer.

Thus, as disclosed herein, the methods and the systems describing the process disclosed in various embodiments, do not need to rely on historical data and sensor data from magnetometer solely to improve magnetism data for geographical regions. Therefore, the methods and the systems provide efficient mechanisms to improve the output of the measurement unit, specifically inertial measurement unit, and subsequently use the improved output of the measurement unit to improve navigation and/or tracking related operations for a device having the measurement unit. The improved magnetism data and the measurement unit reading may be used in navigation applications. This is highly advantageous especially in the case of autonomous vehicles, which benefit from getting accurate and up-to-data magnetism data in real-time. This further ensures faster decision making while driving and thus, safer, and reliable navigation. Even in the case of semi-autonomous or manually driven vehicles, the correct and complete magnetism data ensures better and reliable navigation. Further, the improved magnetism data for different geographical regions may be used to update a map database and thus improve the quality of the map data, which is helpful for all navigation services provided by using the map database.

A system, a method and a computer programmable product are provided for implementing the process for generating improved magnetism data by using a computational network.

In one aspect, a system for generating magnetism data for a measurement unit is disclosed. The system comprises a memory configured to store computer-executable instructions; and at least one processor configured to execute the computer-executable instructions to obtain a set of measurement unit attributes and location information associated with the measurement unit. The set of measurement unit attributes may comprise a first magnetism data for the measurement unit. The at least one processor is further configured to identify a plurality of reference magnetism sources in proximity of the measurement unit, based on the location information. The at least one processor is further configured to obtain reference magnetism data from the plurality of reference magnetism sources. The at least one processor is further configured to generate second magnetism data for the measurement unit, based on the first magnetism data, the reference magnetism data, and a trained computational network.

In additional system embodiments, the at least one processor is further configured to obtain historical magnetometer data for a plurality of geographical regions. The at least one processor is further configured to generate the first magnetism data for a first geographical region of the measurement unit based on the location information, the historical magnetometer data and the trained computational network. The trained machine-learning based computational network is trained on historical magnetometer data for the plurality of geographical regions. The at least one processor is further configured to transmit the first magnetism data to the measurement unit, wherein the measurement unit generates the set of measurement unit attributes using the first magnetism data.

In additional system embodiments, the at least one processor is further configured to determine a magnetism accuracy of the machine-learning based computational network based on the reference magnetism data and the first magnetism data. The at least one processor is further configured to re-train the trained machine-learning based computational network based on the magnetism accuracy, the reference magnetism data, the set of measurement unit attributes and the first magnetism data.

In additional system embodiments, the plurality of reference magnetism sources comprises one or more reference magnetic stations and one or more crowd data sources.

In additional system embodiments, the at least one processor is further configured to generate the second magnetism data for the measurement unit, using the re-trained computational network, transmit the second magnetism data to the measurement unit, and cause to generate, by the measurement unit, updated set of measurement unit attributes.

In additional system embodiments, the measurement unit is associated with at least one of: a vehicle, a compass, or an exploration system.

In additional system embodiments, the at least one processor is further configured to generate navigation instructions based on the second magnetism data and update a map database based on the second magnetism data and the generated navigation instructions.

In additional system embodiments, the measurement unit is at least one of: a nine-axis inertial measurement unit, a six-axis inertial measurement unit, or a three-axis inertial measurement unit.

In additional system embodiments, the set of measurement unit attributes comprise at least one of: the first magnetism data, speed data, orientation data, force data, acceleration information, bearing information, and angular rate information.

In additional system embodiments, to train the computational network, the at least one processor is further configured to receive training data comprising historical magnetism data for a plurality of geographical regions. The historical magnetism data comprises at least one of: one or more historical magnetometer readings, one or more crowd-sourced magnetometer readings, or one or more historical reference magnetism data. The at least one processor is further configured to determine a plurality of features corresponding to magnetism for each of the plurality of geographical regions, using the training data. The at least one processor is further configured to train the machine-learning based computational network to generate test magnetism value for one or more test geographical regions, using the plurality of features and the set of historical magnetism data.

In another aspect, a method for generating magnetism data for a measurement unit is disclosed. The method comprises obtaining a set of measurement unit attributes and location information associated with the measurement unit. The set of measurement unit attributes may comprise a first magnetism data for the measurement unit. The method further comprises identifying a plurality of reference magnetism sources in proximity of the measurement unit, based on the location information. The method further comprises obtaining reference magnetism data from the plurality of reference magnetism sources. The method further comprises generating second magnetism data for the measurement unit, based on the first magnetism data, the reference magnetism data, and a trained computational network.

In yet another aspect, a computer program product comprising a non-transitory computer readable medium having stored thereon computer executable instructions which when executed by at least one processor, cause the processor to conduct operations for generating magnetism data for a measurement unit. The operations comprise obtaining a set of measurement unit attributes and location information associated with the measurement unit. The set of measurement unit attributes may comprise a first magnetism data for the measurement unit. The operations further comprise identifying a plurality of reference magnetism sources in proximity of the measurement unit, based on the location information. The operations further comprise obtaining reference magnetism data from the plurality of reference magnetism sources. The operations further comprises generating second magnetism data for the measurement unit, based on the first magnetism data, the reference magnetism data, and a trained computational network.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF DRAWINGS

Having thus described example embodiments of the invention in general terms, reference will now be made to the accompanying drawings, which are not necessarily drawn to scale, and wherein:

FIG. 1 illustrates a block diagram of an environment where a system for generating improved magnetism data for a measurement unit is implemented, in accordance with one or more example embodiments;

FIG. 2 illustrates a block diagram associated with the system for generating magnetism data for a measurement unit, in accordance with one or more example embodiments;

FIG. 3 illustrates an exemplar architecture showing historical magnetism data of a plurality of geographical regions, in accordance with one or more example embodiments;

FIG. 4 illustrates a schematic diagram for the system for generating magnetism data for the measurement unit, in accordance with one or more example embodiments;

FIG. 5 illustrates an example flowchart for training a machine-learning based computational network for generating magnetism data, in accordance with one or more example embodiments;

FIG. 6 illustrates an example flowchart for generating first magnetism data for a geographical region, in accordance with one or more example embodiments; and

FIG. 7 illustrates an example flowchart for generating second magnetism data for a geographical region, in accordance with one or more example embodiments.

### DETAILED DESCRIPTION

In the following description, for purposes of explanation, numerous specific details are set forth in order to provide a thorough understanding of the present disclosure. It will be apparent, however, to one skilled in the art that the present disclosure may be practiced without these specific details. In other instances, apparatuses and methods are shown in block diagram form only in order to avoid obscuring the present disclosure.

Reference in this specification to “one embodiment” or “an embodiment” means that a particular feature, structure, or characteristic described in connection with the embodiment is included in at least one embodiment of the present disclosure. The appearance of the phrase “in one embodiment” in various places in the specification are not necessarily all referring to the same embodiment, nor are separate or alternative embodiments mutually exclusive of other embodiments. Further, the terms “a” and “an” herein do not denote a limitation of quantity, but rather denote the presence of at least one of the referenced items. Moreover, various features are described which may be exhibited by some embodiments and not by others. Similarly, various requirements are described which may be requirements for some embodiments but not for other embodiments.

Some embodiments of the present invention will now be described more fully hereinafter with reference to the accompanying drawings, in which some, but not all, embodiments of the invention are shown. Indeed, various embodiments of the invention may be embodied in many different forms and should not be construed as limited to the embodiments set forth herein; rather, these embodiments are provided so that this disclosure will satisfy applicable legal requirements. Like reference numerals refer to like elements throughout. As used herein, the terms “data,” “content,” “information,” and similar terms may be used interchangeably to refer to data capable of being transmitted, received and/or stored in accordance with embodiments of the present invention. Thus, use of any such terms should not be taken to limit the spirit and scope of embodiments of the present invention.

As defined herein, a “computer-readable storage medium,” which refers to a non-transitory physical storage medium (for example, volatile or non-volatile memory device), may be differentiated from a “computer-readable transmission medium,” which refers to an electromagnetic signal.

The embodiments are described herein for illustrative purposes and are subject to many variations. It is understood that various omissions and substitutions of equivalents are contemplated as circumstances may suggest or render expedient but are intended to cover the application or implementation without departing from the spirit or the scope of the present disclosure. Further, it is to be understood that the phraseology and terminology employed herein are for the purpose of the description and should not be regarded as limiting. Any heading utilized within this description is for convenience only and has no legal or limiting effect.

### DEFINITIONS

The term “measurement unit” may refer to an electronic device used for measuring attributes of an object housing the measurement unit. For example, the measurement unit may be an inertial measurement unit or an inertial navigation system. The measurement unit may be used for measuring, for example, acceleration, altitude, speed, angular rate, heading, velocity, position, and inertial reference frame of the object. In an example, the measurement unit may include one or more sensors, such as one or more accelerometers, one or more gyroscope, and one or more magnetometers.

In an example, given a location of the object and map data, the measurement unit may measure acceleration and angular position of the object. Based on the measured output, the location and the map data, the measurement unit may identify reference point or reference frame of the object and movement of the object. For example, the measurement unit may output where the object is located geographically during due course of motion at a particular time without any need to communicate with or receive communication from any outside components, such as satellites or land radio transponders.

The term “measurement unit attributes” may refer to data generated or measured by a measurement unit. The measured data or the measurement unit attributes may relate to an object with which the measurement unit is associated. For example, in case of a measurement unit comprising one or more accelerometers, one or more gyroscope, and one or more magnetometers, the measurement unit attributes may include, for example, speed, velocity, acceleration, altitude, angular rate, heading or orientation, position, yaw rotation, pitch rotation, roll rotation, bearing information, and so forth.

The term “magnetism data” may refer to information or readings relating to orientation of earth's magnetic field at a geographical region. In an example, the magnetism data may include magnetic field, magnetic deflection, variation in the magnetic field (magnetic variation), magnetic dipole moment, or a combination thereof. In an example, magnetism data for a geographical region may include historical magnetometer readings for the geographical region. In another example, magnetism data for a geographical region may include real-time magnetic field reading generated for the geographical region.

The term “geographical region” may refer to an area and/or a zone on earth's surface. A geographical region may have corresponding physical characteristics, such as shape, size, longitude, latitude, and so forth. A geographical region may comprise of natural as well as artificial entities, for example, trees, rocks, roads, buildings, bridges etc.

The term “reference magnetism source” may refer to a reference source or a reference station that may monitor magnetism value or magnetic field value for a corresponding geographic region on the earth's surface. In an example, the reference magnetism source may be a reference magnetic station or a magnetic base station that may monitor the earth's crust to determine magnetism data for one or more geographic regions. For example, the reference magnetic station may comprise high sensitivity and high resolution magnetic sensors.

The term “computational network” may refer to an artificial intelligence based network or model. In an example, the computational network may be a machine learning network or model that is trained to process data, identify patterns in the data and generate/predict certain output based on the identified patterns. In an example, the computational network may be a neural network. The neural network may be trained using supervised learning, unsupervised learning, semi-supervised learning, reinforcement learning, or a combination thereof.

### END OF DEFINITIONS

A system, a method, and a computer program product are provided for generating magnetism data for a measurement unit. The conventional magnetism data, such as historical magnetism data stored in a database or magnetism data collected from low grade magnetic sensors may be inaccurate and have accumulated error or drift. The inaccuracy in the magnetism data may affect operation of measurement units resulting in inaccurate final output. Moreover, a substantial increase in cost may have to be incurred to fuse high grade magnetometers in the measurement units. In addition, such high grade magnetometers may affect size, robustness and mobility of the measurement unit. Therefore, magnetism data need to be corrected while ensuring that the measurement unit is simplex, robust and easy to carry.

Various embodiments are provided herein for generating improved magnetism data by reducing or eliminating dependency on magnetometers, such that a trained machine-learning based computational network generates the accurate magnetism data for a geographical region for the measurement unit. The improved magnetism data may be used for accurate estimation of heading or orientation and thus position of an object. In this manner, data for navigation related operations, exploration or discovery of minerals, metals, etc. may be improved.

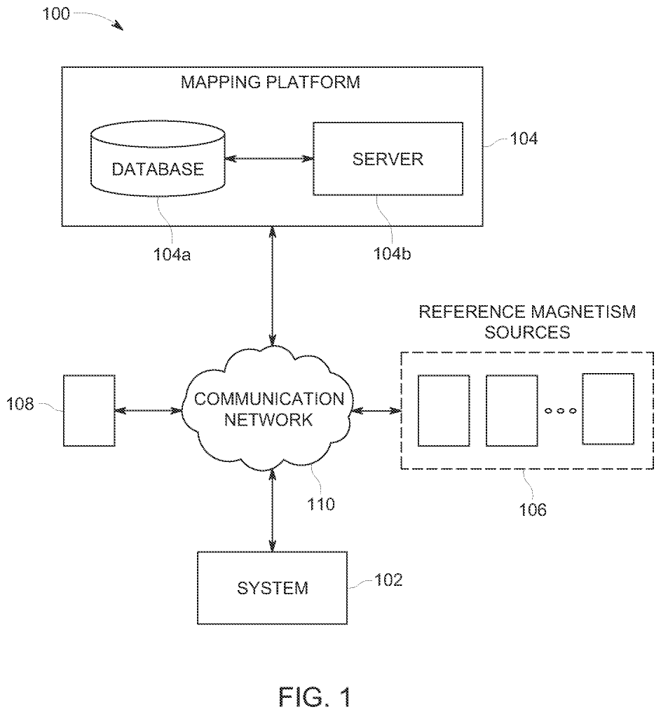

FIG. 1 illustrates a block diagram of an environment 100 where a system 102 for generating improved magnetism data for a measurement unit is implemented, in accordance with an example embodiment. As illustrated in FIG. 1, the environment 100 may comprise the system 102, a mapping platform 104, reference magnetism sources 106, a measurement unit 108, and a communication network 110. The mapping platform 104 may further comprise a database 104a and a server 104b. The components described in the block diagram 100 may be further broken down into more than one component such as one or more sensors or application in user equipment and/or combined together in any suitable arrangement. Further, it is possible that one or more components may be rearranged, changed, added, and/or removed without deviating from the scope of the present disclosure.

In various embodiments, the system 102 may be on cloud or located remotely from the measurement unit 108. In certain cases, the measurement unit may be onboarding an object, such as a vehicle, a compass, or an exploration device. For example, the measurement unit 108 may be associated with a navigation system installed in a vehicle for detecting or measuring a set of measurement unit attributes of the vehicle. Examples of the set of measurement unit attributes may include, but are not limited to, the first magnetism data, speed data, orientation data, force data, acceleration information, bearing information, and angular rate information.

In various embodiments, the reference magnetism sources 106 may include, without limitation, one or more reference magnetic stations and one or more crowd data sources. The one or more reference magnetic stations may be magnetic base stations that monitor magnetic variation for plurality of geographic regions on earth's crust. Moreover, the one or more crowd data sources may be crowd sourced magnetometer data from, for example, smartphones. The one or more crowd data sources may include one or more sensors and/or a communication interface (not shown in the FIG. 1). A magnetic sensor in the one or more crowd data sources may acquire magnetism data relating to a corresponding geographic region. The one or more reference stations and the one or more crowd data sources may transmit the magnetism data to the system 102. Such magnetism data relating to plurality of geographic regions acquired and transmitted by the reference magnetism sources 106 may have to be optimized or may be used to generate magnetism data for other geographical regions, for example, a geographical region associated with the measurement unit 108. In an example, magnetism data corresponding to the geographical region associated with the measurement unit 108 may include synthetic or optimized magnetic field data of the geographical region. Further, the measurement unit 108 may use other sensors, such as accelerometers and gyroscope to generate accurate measurement unit attributes based on the generated accurate magnetism data. For example, an output of the measurement unit 108 may be used by a navigation system or a navigation device.

Although the present disclosure describes the use of the generated magnetism data by measurement units, such as inertial measurement units (IMUs), however, this should not be construed as limiting. The generated accurate magnetism data may be used for orientation or direction detection in any device. Moreover, the examples of the present disclosure define the use of the final output of the measurement unit 108 in navigation operations. However, this should not be construed as a limitation. In other examples of the present disclosure, the final output of the measurement unit may be used for, for example, fitness tracking, exploration, gaming, animation application, sports techniques training, motor skills training, and the like.

Further, the system 102 may be communicatively coupled with the mapping platform 104, the reference magnetism source 106 and the measurement unit 108 over the communication network 110. The communication network 110 may be wired, wireless, or any combination of wired and wireless communication networks, such as cellular, Wi-Fi, internet, local area networks, or the like.

The mapping platform 104 may comprise the database 104a for storing data, and the processing server 104b for conducting the processing functions associated with the mapping platform 104. The database 104a may store map data relating to land maneuvering, airspace maneuvering and/or water maneuvering. In an example, the database 104a may store road segment data or link data, point of interest (POI) data, lane marking data, road intersections or node data, road obstacles related data, traffic objects related data, posted signs related data (such as road sign data), data related to permissible driving directions, data about valid paths based on legally permissible road geometries or the like, and so forth. The database 104a may also include cartographic data and/or routing data.

The database 104a may also include historical data, specifically, historical magnetism data. For example, the historical magnetism data may include historical magnetometer data collected from survey-grade or other highly accurate magnetometers. In an example, the historical magnetism data may include historical crowd sourced magnetometer data from various crowdsourcing devices, and the historical reference magnetism data from various reference magnetic stations. These examples of historical magnetism data should not be construed as limiting, and historical magnetism data may include historical magnetic field data from other sources.

The processing server 104b may comprise one or more processors configured to process requests received from the system 102. The processor may fetch map data and/or historical magnetism data from the database 104a and transmit the same to the system 102 in a format suitable for use by the system 102. In some example embodiments, as disclosed in conjunction with the various embodiments disclosed herein, the system 102 may be used to generate improved and accurate magnetism data of a geographical region for a measurement unit.

In operation, the system 102 may obtain a set of measurement unit attributes and location information associated with the measurement unit 108. The set of measurement unit attributes may include readings of one or more sensors within the measurement unit 108. For example, the measurement unit attributes may include, but is not limited to, altitude, velocity and position of the measurement unit 108. Such measurement unit attributes may be determined based on readings of one or more accelerometers and one or more gyroscopes as well as orientation or direction of the measurement unit 108, wherein the orientation or direction of the measurement unit 108 is determined based on magnetism data associated with the measurement unit 108. Subsequently, the measurement unit attributes may be associated with or indicative of first magnetism data for the measurement unit 108. Moreover, the location information may indicate a geographical region, such as latitude and longitude associated with the measurement unit 108. For example, a global positional sensor (GPS) onboard the measurement unit 108 may collect the location information and transmit it to the system 102. In an example, the measurement unit 108 may be an inertial measurement unit.

Further, the system 102 may identify a plurality of reference magnetism sources in proximity of the measurement unit 108, based on the location information. In an example, the system 102 may select one or more reference magnetic stations nearest to the geographical region of the measurement unit 108. In another example, the system 102 may select one or more crowd data sources nearest to the measurement unit 108. The system 102 may obtain reference magnetism data from the plurality of reference magnetism sources. In an example, the reference magnetism data may include magnetic variation or magnetic field value monitored by the plurality of reference magnetism sources in their corresponding geographic regions.

Based on the first magnetism data, the reference magnetism data, and a trained computational network, the system 102 may generate second magnetism data for the measurement unit 108. In particular, the system 102 may employ a trained machine-learning based computational network to generate accurate second magnetism data for the geographical region associated with the measurement unit 108. For example, the machine-learning based computational network may be a neural network model. Moreover, the machine-learning based computational network may be trained on historical magnetism data associated with plurality of different geographical regions collected over a span of time, such as over a span of 1 month, 1 year, 5 years, 10 years, 20 years, 45 years, 50 years, and so forth.

In particular, the first magnetism data may be determined based on the set of measurement unit attributes obtained from the measurement unit 108. For example, the first magnetism data may be magnetometer readings of a low-grade magnetometer onboard the measurement unit 108, or magnetism data obtained from any other source based on which measurement unit 108 may determine its output. In an example, the measurement unit 108 may obtain the first magnetism data from the database 104a, the system 102, crowd sources, database associated with crowd sources, or any other database or memory storing magnetism data. To this end, the first magnetism data may not be accurate; therefore, the system 102 may be configured to correct the first magnetism data. In this regard, the system 102 may generate the second magnetism data based on the reference magnetism data, using the machine-learning based computational network. For example, the system 102 may obtain reference magnetism data for geographical regions associated with the reference magnetic sources. Further, the system 102 may generate the second magnetism data for a geographical region associated with the measurement unit 108 based on the first magnetism data and the reference magnetism data and using the trained machine-learning based computational network.

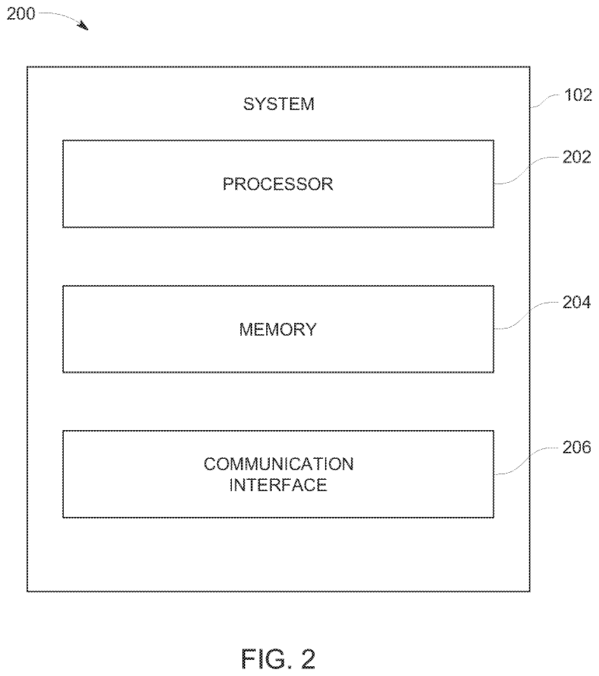

FIG. 2 illustrates a block diagram 200 associated with the system 102 for generating magnetism data for a measurement unit, in accordance with an embodiment disclosed herein. The embodiments of FIG. 2 are explained in conjunction with FIG. 1.

The system 102 may include at least one processor 202, a memory 204, and at least one communication interface 206. The at least one processor 202 (referred to as processor 202, hereinafter) may be embodied in a number of different ways. The memory 204 may be non-transitory and may include, for example, one or more volatile and/or non-volatile memories.

The processor 202 of the system 102 may be configured to determine the first magnetism data for the measurement unit 108, based on the measurement unit attributes. Further, based on the first magnetism data and the reference magnetism data, the processor 202 may generate second magnetism data for the measurement unit 108. The processor 202 may be further configured to update the database 104a for assisting navigation operations in a geographical region associated with the measurement unit 108.

The processor 202 is configured to generate a historical database. In an example, the historical database may include historical magnetism data of a plurality of geographic regions collected over a period of time. For example, the historical magnetism data may be collected from high accuracy survey-grade magnetometers, crowd data sources, and/or reference magnetic stations. For example, the historical database may be a three-dimensional earth model depicting one or more accumulated historical magnetism data for one or more geographic regions on the earth's surface.

It may be noted that historical magnetism data may be unavailable for certain geographical regions of the earth. In such a case, the processor 202 is configured to generate magnetism data for the geographical regions, based on the historical magnetism database. Further, the generated magnetism data may be transmitted to a measurement unit, such as the measurement unit 108 for assisting in navigation operations.

To improve the historical magnetism data and/or a generated magnetism data associated with a geographic region, the processor 202 may be configured to start an optimization process by identifying reference magnetism sources in proximity of the geographic region and the measurement unit 108. For example, the processor 202 may obtain reference magnetism data from the reference magnetism sources, wherein the reference magnetism data may relate to one or more geographical regions associated with the reference magnetism sources. Based on the reference magnetism data, the processor 202 may generate accurate second magnetism data for the geographical region associated with the measurement unit. The accurate second magnetism data may be generated in real-time. Based on the accurate second magnetism data, the measurement unit 108 may also correct output or readings of one or more sensors within the measurement unit 108. Such one or more sensors may include, for example, one or more accelerometers and one or more gyroscope.

In an example, the processor 202 may be configured to execute programmable instructions that are configured to implement a computational network. For example, the machine-learning based computational network may be a neural network having a deep learning architecture. It may be noted that magnetic field of the earth may be different for different regions of the earth. The machine-learning based computational network may be configured to generate a computational model for replicating paleo-magnetism property of rocks by determining magnetic deviation for different geographical regions caused due to movement of earth's magnetic poles. Therefore, the machine-learning based computational network may be able to determine movement of the magnetic poles and the subsequent deviation at a particular geographical region, i.e., latitude and longitude. In this manner, the processor 202 and the machine-learning based computational network may remove dependency of a magnetometer in the measurement unit 108.

For example, the processor 202 may update the historical database or the three-dimensional earth model, based on the generated second magnetism data for a geographical region, say, a first geographical region. Further, based on the generated second magnetism data, the measurement unit 108 may correct orientation information relating to the measurement unit 108 and/or an object, such as a vehicle associated with the measurement unit 108. Moreover, the measurement unit 108 may also use the second magnetism data to correct measurement of yaw rotation, pitch rotation, and roll rotation using the one or more accelerometers, the one or more gyroscope and the second magnetism data. In this manner, accurate output of the measurement unit 108 and correct yaw rotation data may be generated using a six-axis IMU, i.e., without a magnetometer, thereby making the accurate measurement unit cost-effective.

In an example, the processor 202 may be configured to generate navigation instructions based on the second magnetism data. In an example, the navigation instructions may be generated based on updated measurement unit attributes generated by the measurement unit 108 using the second magnetism data. For example, the navigation instructions may be generated using GPS technology and map data, for a vehicle travelling from the first geographical region. In an example, the navigation instructions may include navigation directions or route, position of the vehicle on routes associated with the navigation directions, speed of the vehicle, orientation of the vehicle, and so forth. Thereafter, the processor 202 may update a map database, such as the database 104a based on the second magnetism data and the generated navigation instructions. In certain cases, the vehicle may be an autonomous or an unmanned vehicle. In such a case, the navigation instructions may also include instructions to control movement of the vehicle by controlling, for example, speed, altitude, velocity, acceleration, orientation or heading, angular rate, and so forth. Moreover, the database 104a may be updated to store the accurate magnetism data and navigation instruction generated based on the accurate magnetism data.

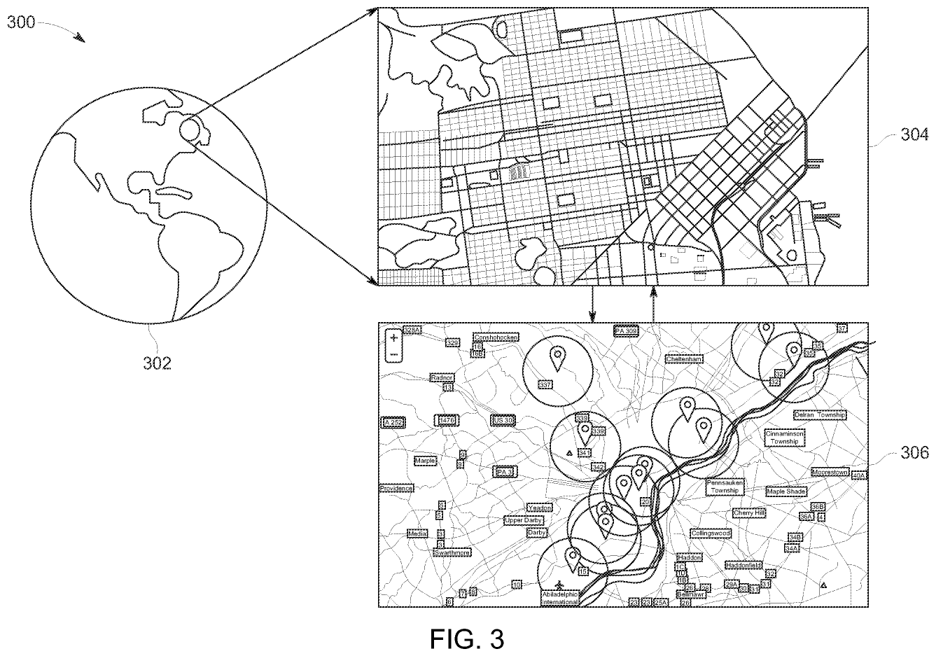

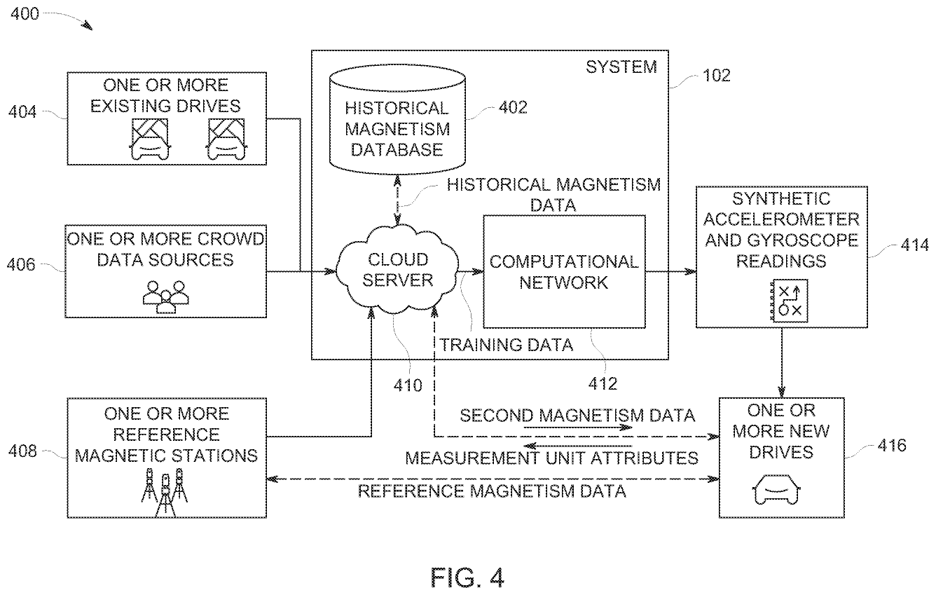

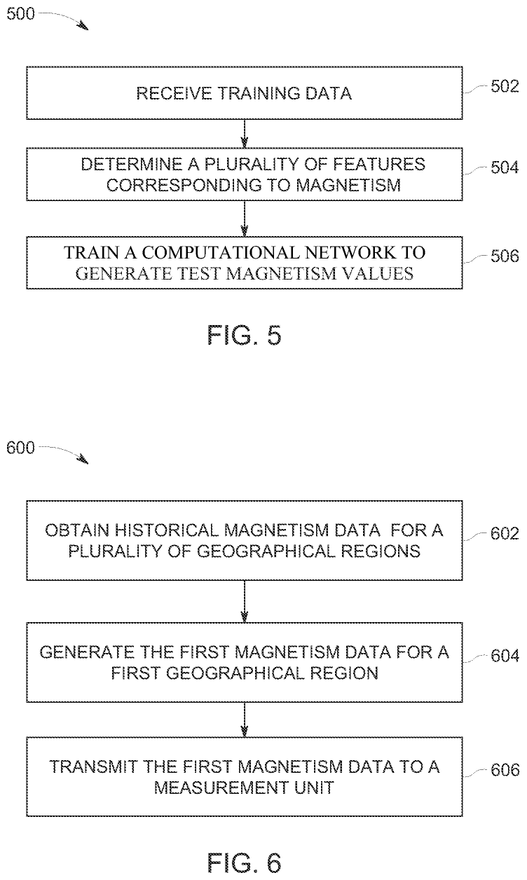

In certain cases, the processor 202 may also be configured to update or re-train the computation network, based on the second magnetism data to tackle change induced in magnetic field over time for the first geographical region. A manner in which the improved magnetism data is generated is described in detail in conjunction with FIG. 3, FIG. 4 and FIG. 5.

FIG. 3 illustrates an exemplar architecture 300 showing historical magnetism data 302 of a plurality of geographical regions, in accordance with one or more example embodiments. The historical magnetism data 302 is stored in form of, for example, a two-dimensional or a three-dimensional earth's model. As may be noted, the earth's model may include various geographical regions present on the earth's surface. Moreover, one or more historical magnetometer readings, historical magnetic field value, magnetic deflection, magnetic variation, etc. may be stored as historical magnetism data for a particular geographical region form the various geographical regions.

In an example, historical magnetism data for a geographical region 304 may include historical magnetometer recordings or readings 306. For example, FIG. 3 shows a zoomed-in view of historical magnetism data 302 corresponding to the geographical region 304. The historical magnetism data 302 includes historical magnetometer readings 306 that may be collected over a period of time, such as 30 days, one year, five years, 15 years, 25 years, 50 years and so forth. For example, historical magnetometer readings may be collected form highly accurate magnetometers across the earth's surface. Further, the historical magnetometer readings may be mapped based on corresponding geographical location.

Further, the historical magnetism data for the geographical region 304 may be associated with one or more reference magnetic stations, one or more crowd data source and map data. To this end, the historical magnetism data for the geographical region 304 may also include historical reference magnetism data from the one or more reference magnetic stations, and historical magnetism data from the one or more crowd data source.

In an example, the historical magnetism data for the geographical region 304 may be used to generate an accurate and real-time second magnetism data for the geographical region 304. The second magnetism data may be transmitted to the measurement unit 108. Based on the second magnetism data, the measurement unit 108 may correct or enhance sensor data from, for example, one or more accelerometers and one or more gyroscope.

FIG. 4 illustrates a schematic diagram 400 for the system 102 for generating magnetism data for the measurement unit 108, in accordance with an example embodiment disclosed herein. The network environment 400 comprises the system 102. The system 102 is configured to obtain historical magnetism data and create a historical magnetism database 402. In an example, a cloud server 410 of the system 102 obtains the historical magnetism data from one or more existing drives 404, one or more crowd data sources 406, and one or more reference magnetic stations 408. The system 102 may obtain historical magnetism data for a plurality of geographical regions.

In an example, the historical magnetism database 402 may be a three-dimensional or a two-dimensional earth model having one or more historical magnetism values corresponding to one or more geographical regions form the plurality of geographical regions. In an example, the historical magnetism database 402 may include historical magnetism data from the one or more existing drives 404. For example, the one or more existing drives 404 may be a database comprising spatially mapped historical magnetometer readings, for example, form 9-axis IMUs. In an example, processed as well as raw magnetometer readings may be recorded along with corresponding spatial component or geographical location to create the historical magnetism database 402 or earth's model.

Further, the one or more reference magnetic stations 408 may be datum like physical stations that may be placed at corresponding geographical locations for real-time referencing. The one or more reference magnetic stations 408 may be used to monitor and/or correct magnetism data for corresponding geographical location. For example, historical data generated by the one or more reference magnetic stations 408 may also be stored to create the historical magnetism database 402 or earth's model.

In addition, magnetometer data may be collected from the one or more crowd data sources 406. Examples of the crowd data sources 406 may include, but are not limited to, smartphones equipped with magnetometer, probe devices, probe vehicles, compass, and so forth. The magnetometer data from the crowd data sources 406 may be crowd sourced to spatially enhance the historical magnetism database 402 or earth's model. In this manner, the historical magnetism data from the one or more existing drives 404, the magnetometer data from the crowd data sources 406 and the historical data generated by the one or more reference magnetic stations 408 may enable the artificial paleo-magnetism memory, i.e., create the historical magnetism database 402. To this end, the historical magnetism database 402 may include historical magnetism data for various geographical regions, for which historical data is available.

The historical magnetism database 402 may be deployed on the cloud server 410. For example, the cloud server 410 may create and train a machine-learning based computational network 412 based on the historical magnetism database 402. A manner in which the machine-learning based computational network 412 is trained in described in detail in conjunction with FIG. 5.

The trained machine-learning based computational network 412 may be operated to generate accurate synthetic magnetism data for geographical locations and transmitting the generated magnetism data to the measurement unit 108. A manner in which the trained machine-learning based computational network 412 is operated to generate synthetic magnetism data is described in detail in conjunction with FIG. 6.

The measurement unit may utilize the generated synthetic magnetism data to determine yaw rotation value. Further, the generated synthetic magnetism data may be used for generating synthetic gyroscopic and accelerometer readings 414 for one or more new drives 416. In particular, the generated magnetism data may be used for correction and/or increasing precision of output generated by the one or more new drives 416, thereby generating synthetic gyroscopic and accelerometer readings 414. To this end, the one or more new drives 416 having only 6-axis measurement unit or 3-axis measurement unit may be able to obtain accurate magnetism data and accordingly perform navigation or tracking related operations. In certain cases, a new drive having low grade magnetometer, i.e., low grade or overly sensitive 9 axis measurement unit, may also benefit from the synthetic magnetism data. In such a case, a measurement unit of the new drive may be able to enhance its output using the synthetic magnetism data.

Referring to FIG. 5, an example flowchart of a method 500 for training a machine-learning based computational network for generating magnetism data is illustrated, in accordance with an example embodiment. In an example, the machine-learning based computational network 412 may be a machine learning based network. In an example embodiment, the machine-learning based computational network 412 may be a deep learning neural network, such as a generative-adversarial network. As may be noted, in the generative-adversarial network, two neural networks, namely generator network and discriminator network may compete with each other to become more accurate in their predictions.

At 502, training data is received. In an example, the training data comprises historical magnetism data for a plurality of geographical regions. For example, the historical magnetism data comprises at least one of: one or more historical magnetometer readings 404, one or more crowd-sourced magnetometer readings 406, or one or more historical reference magnetism data 408. In an example, the training data is obtained from the historical magnetism database 402.

As described above, the system 102 may create a spatially mapped earth's artificial model to store magnetic readings and properties, i.e., historical magnetism data. Based on historical magnetism data stored in the earth's model, the machine-learning based computational network 412 is developed to rectify and assess the impact of earth's magnetism at certain geographical locations on gyroscope and accelerometer. In an example, the machine-learning based computational network 412 may correct or enhance a final output of a gyroscope and an accelerometer in real-time for use in autonomous vehicles and/or terrestrial mapping.

At 504, a plurality of features corresponding to magnetism is determined for each of the plurality of geographical regions, using the training data. In an example, the machine-learning based computational network 412 may be made to run on the training data to identify the plurality of features corresponding to magnetism from the training data. In an example, the generator network may determine and acquire the plurality of features, for example, magnetic deviation, rate of change, etc.

At 506, the machine-learning based computational network 412 is trained to generate test magnetism value for one or more test geographical regions, using the plurality of features and the set of historical magnetism data. For example, the generator network may produce synthetic magnetism data as output for the one or more test geographical regions. Further, the discriminator network generates a probability to represent authenticity of the generated synthetic magnetism data. This process may be repeated until a predefined accuracy of the machine-learning based computational network 412 is achieved.

Once the machine-learning based computational network 412 is trained, the machine-learning based computational network 412 is used to generate synthetic magnetism data for certain geographical regions. For example, magnetism data may not be available for the geographical regions. In another example, magnetism data for the geographical regions may be inaccurate.

Typically, magnetic readings or yaw is determined by hardware/sensors called magnetometer. Magnetometers are overly sensitive to environment. Moreover, high accuracy magnetometers for autonomous vehicles (AVs) are costly and inhibit scalability of expensive AVs. To address the aforementioned problem, the machine-learning based computational network 412 is trained to generate synthetic magnetic data for geographical regions that are accurate and precise.

Referring to FIG. 6, an example flowchart of a method 600 for generating first magnetism data for a geographical region is illustrated, in accordance with an example embodiment.

In this regard, at 602, historical magnetism data for a plurality of geographical regions is obtained. In an example, the historical magnetism data may include historical magnetometer readings, historical reference magnetism data and historical crowd sourced magnetism data. Moreover, the plurality of geographical regions may be different geographical regions on the earth's crust.

At 604, the first magnetism data for a first geographical region of the measurement unit is generated based on location information and the trained machine-learning based computational network 412. As described in conjunction with FIG. 5, the machine-learning based computational network 412 may be trained on the historical magnetism data. Further, the trained machine-learning based computational network 412 may generate the first magnetism data for a first geographical region. The first magnetism data may indicate a magnetic field and magnetic deviation or variations at the first geographical region.

At 606, the first magnetism data is transmitted to the measurement unit 108. The measurement unit 108 generates the set of measurement unit attributes using the first magnetism data. In an example, the measurement unit 108 may be a three-axis inertial measurement unit, a six-axis inertial measurement unit, or a nine-axis inertial measurement unit. For example, the three-axis inertial measurement unit may include one of: an accelerometer, a gyroscope, or a magnetometer. Further, the six-axis inertial measurement unit may include one of: an accelerometer and a gyroscope, an accelerometer and a magnetometer, or a gyroscope and a magnetometer. Similarly, the nine-axis inertial measurement unit may include an accelerometer, a gyroscope and a magnetometer.

In an example, the measurement unit attributes generated by the measurement unit may include readings from the accelerometer, the gyroscope, and/or the magnetometer. For example, the measurement unit attributes comprise at least one of: the first magnetism data, speed data, orientation data, force data, acceleration information, bearing information, and angular rate information.

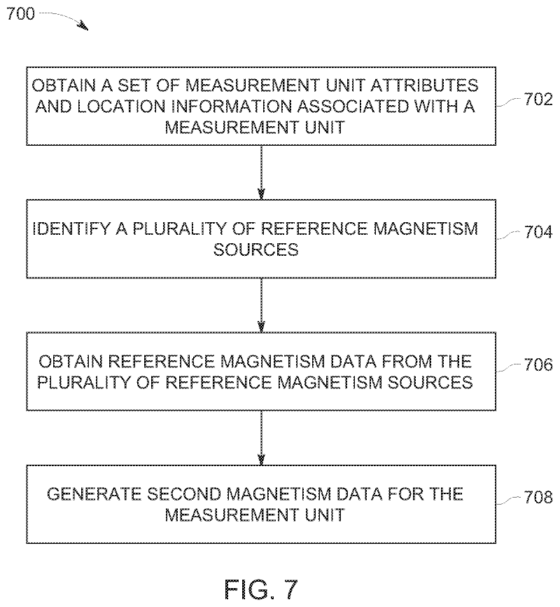

After the measurement unit attributes are generated, the output of the measurement unit 108 may have to be re-checked to ensure correct operation of the system 102 and the machine-learning based computational network 412. In one example, an output of the measurement unit 108 may be based on the first magnetism data generated previously by the system 102. In another example, an output of the measurement unit 108 may be based on a historical magnetism data stored in, for example, the historical magnetism database 402. In yet another example, an output of the measurement unit 108 may be based on an inaccurate magnetometer reading from a low-grade magnetometer of the measurement unit 108. To this end, the first magnetism data may be inaccurate and may have to be corrected. A manner in which the measurement unit attributes, and the first magnetism data generated by the measurement unit 108 may be corrected is described in detail in conjunction with FIG. 7.

FIG. 7 illustrates an example flowchart of a method 700 for generating second magnetism data for a geographical region, in accordance with an example embodiment. The second magnetism data may be more accurate magnetism data for the geographical region. In this manner, the system 102 may correct or enhance readings of the measurement unit 108.

At 702, a set of measurement unit attributes and location information associated with the measurement unit 108 are obtained. The set of measurement unit attributes may be generated by the measurement unit 108 based on the first magnetism data associated with the corresponding geographical regions, say, a first geographical region. Moreover, the location information may include information relating to the first geographical region. The location information may include, for example, latitude and longitude.

At 704, a plurality of reference magnetism sources in proximity of the measurement unit 108 may be identified. In an example, only one reference magnetism source may be present in proximity of the measurement unit 108. The reference magnetism source may include a reference magnetic station. For example, the reference magnetism source may be a highly accurate magnetism data source.

At 706, the reference magnetism data is obtained from the plurality of reference magnetism sources. The reference magnetism data may include magnetism data, such as magnetic field value, magnetic deviation, etc. for a geographical region associated with the plurality of reference magnetism sources.

Thereafter, at 708, the second magnetism data is generated for the measurement unit 108. The second magnetism data is generated based on the first magnetism data, the reference magnetism data, and the trained machine-learning based computational network 412. In an example, the second magnetism data may be generated when the magnetic accuracy is less than a predefined threshold, such as 60%, 75%, 80%, and so forth. Moreover, the second magnetism data may be more accurate than the first magnetism data for the first geographical region.

In an example, the system 102 may determine magnetism accuracy based on the reference magnetism data and the first magnetism data. For example, the first magnetism data may be compared with the reference magnetism data to determine the magnetism accuracy. Based on the comparison, the system 102 may determine a rate or percentage of accuracy between the first magnetism data and the reference magnetism data. Further, the system 102 may re-train the trained machine-learning based computational network 412 based on the magnetism accuracy, the reference magnetism data, the set of measurement unit attributes and the first magnetism data. In particular, the trained machine-learning based computational network 412 may be re-trained to increase the accuracy of the trained machine-learning based computational network 412. For example, the trained machine-learning based computational network 412 may be re-trained to predict synthetic magnetism data more accurately. In this regard, the magnetism accuracy, the reference magnetism data, the set of measurement unit attributes, the first magnetism data, or a combination thereof may be provided as input to the trained machine-learning based computational network 412 for processing. The trained machine-learning based computational network 412 may identify features relating to generation of magnetism data based on the input and generates the second magnetism data for the first geographical region.

Continuing further, the second magnetism data may be generated for the measurement unit 108, using the re-trained machine-learning based computational network 412. The second magnetism data may be transmitted to the measurement unit 108, for example, over a wired or wireless communication network. Further, the measurement unit 108 may generate updated set of measurement unit attributes based on the second magnetism data. In an example, the measurement unit 108 may correct readings of, for example, accelerometer and gyroscope, based on the second magnetism data. The correct readings of the accelerometer and the gyroscope may be used to generate the updated measurement unit attributes.

Accordingly, blocks of the flowcharts 500, 600 and 700 support combinations of means for performing the specified functions and combinations of operations for performing the specified functions for performing the specified functions. It will also be understood that one or more blocks of the flowcharts 500, 600 and 700, and combinations of blocks in the flowcharts 500, 600 and 700, can be implemented by special purpose hardware-based computer systems which perform the specified functions, or combinations of special purpose hardware and computer instructions.

Alternatively, the system 102 may comprise means for performing each of the operations described above. In this regard, according to an example embodiment, examples of means for performing operations may comprise, for example, the processor 202 and/or a device or circuit for executing instructions or executing an algorithm for processing information as described above.

On implementing the method 500, 600 and 700 disclosed herein, the end result generated by the system 102 is a tangible magnetism data for measurement units for accurate tracking of objects, such as vehicles, exploration systems, etc.

In an example, the measurement unit 108 is associated with at least one of: a vehicle, a compass, or an exploration system. Additionally, the vehicle may include a motor vehicle, a non-motor vehicle, an automobile, a car, a scooter, a truck, a van, a bus, a motorcycle, a bicycle, a Segway, and/or the like. The vehicle may be an autonomous vehicle, a semiautonomous vehicle, or even a manual vehicle.

In an example, the measurement unit 108 may be installed within a vehicle for performing navigation related operations. In such a case, the system 102 may generate navigation instructions based on the updated measurement unit attributes. For example, the updated measurement unit attributes may be used to track movement, speed, acceleration, orientation, position, angular rate, and bearing information of the vehicle. Subsequently, based on the tracking of the vehicle, the navigation instructions may be generated and/or updated. In case of an autonomous vehicle, the navigation instructions may be used to control the vehicle.

In this manner, six-axis measurement units or inertial measurement units having accelerometer and gyroscope may be used in place of nine-axis inertial measurement units (IMU). Moreover, if a nine-axis IMU is used along with embodiments of the present disclosure then improvement in performance of the nine-axis IMU may be achieved due to accurate magnetism data. In particular, the magnetism data is generated in a remote server by a computational network; therefore, no change is required on hardware. This enables improving performance of IMUs in a very cost effective manner. Further, the magnetism data generated using embodiments of the present disclosure may eliminate errors due to magnetic bias in magnetometers.

In some embodiments, the system 102 may comprise one or more measurement units for example as a part of an in-vehicle navigation system, a navigation app in a mobile device and the like. In each of such embodiments, the system 102 may be communicatively coupled to the components shown in FIG. 1 to conduct the desired operations and wherever required modifications may be possible within the scope of the present disclosure. In any which way, a vehicle may be able to gain advantage of the system 102 and methods 500, 600 and 700, irrespective of the type of the vehicle.

In one embodiment, the measurement unit 108 may be directly coupled to the system 102 via the communication network 110. In another embodiment, the measurement unit 108 may be coupled to the system 102 via an OEM cloud and the communication network 110. For example, the measurement unit 108 may be a consumer vehicle (or a part thereof) and may be a beneficiary of the services provided by the system 102. In some example embodiments, the measurement unit 108 may serve the dual purpose of a data gatherer and a beneficiary device. For example, the measurement unit 108 may be installed in the vehicle and is configured to monitor movement features relating to the vehicle by using accelerometers and gyroscope. The measurement unit 108 then generates measurement unit attributes based on the readings and the first magnetism data. The system 102 uses optimization techniques to correct the first magnetism data or generate accurate second magnetism data, improve accuracy of the measurement unit attributes and generate navigation instructions.

Returning to FIG. 1, the system 102 may be the server 104b of the mapping platform 104 and therefore may be co-located with or within the mapping platform 104. For example, the system 102 may be embodied as a cloud based service, a cloud based application, a cloud based platform, a remote server based service, a remote server based application, a remote server based platform, or a virtual computing system. In some other embodiments, the system 102 may be an OEM (Original Equipment Manufacturer) cloud. The OEM cloud may be configured to anonymize any data received by the system 102, such as from the measurement unit 108, before using the data for further processing, such as before sending the data to the mapping platform 104 and/or the system 102. In some embodiments, anonymization of data may be done by the mapping platform 104.

In some embodiments, the communication network 110 may include one or more networks such as a data network, a wireless network, a telephony network, or any combination thereof. It is contemplated that the data network may be any local area network (LAN), metropolitan area network (MAN), wide area network (WAN), a public data network (e.g., the Internet), short range wireless network, or any other suitable packet-switched network, such as a commercially owned, proprietary packet-switched network, e.g., a proprietary cable or fiber-optic network, and the like, or any combination thereof. In addition, the wireless network may be, for example, a cellular network and may employ various technologies including enhanced data rates for global evolution (EDGE), general packet radio service (GPRS), global system for mobile communications (GSM), Internet protocol multimedia subsystem (IMS), universal mobile telecommunications system (UMTS), etc., as well as any other suitable wireless medium, e.g., worldwide interoperability for microwave access (WiMAX), Long Term Evolution (LTE) networks (for e.g. LTE-Advanced Pro), 5G New Radio networks, ITU-IMT 2020 networks, code division multiple access (CDMA), wideband code division multiple access (WCDMA), wireless fidelity (Wi-Fi), wireless LAN (WLAN), Bluetooth, Internet Protocol (IP) data casting, satellite, mobile ad-hoc network (MANET), and the like, or any combination thereof.

In some embodiments, the map data may be collected by end-user vehicles which use vehicles' on-board sensors to detect data about various entities such as road objects, lane markings, links, and the like. These vehicles are also referred to as probe vehicles and form an alternate form of data source for map data collection, along with ground truth data. Additionally, data collection mechanisms like remote sensing, such as aerial or satellite photography may be used to collect the map data for the map database 104a.

Returning to FIG. 2, the processor 202 may be embodied as one or more of various hardware processing means such as a coprocessor, a microprocessor, a controller, a digital signal processor (DSP), a processing element with or without an accompanying DSP, or various other processing circuitry including integrated circuits such as, for example, an ASIC (application specific integrated circuit), an FPGA (field programmable gate array), a microcontroller unit (MCU), a hardware accelerator, a special-purpose computer chip, or the like. As such, in some embodiments, the processor 202 may include one or more processing cores configured to perform independently. A multi-core processor may enable multiprocessing within a single physical package. Additionally or alternatively, the processor 202 may include one or more processors configured in tandem via the bus to enable independent execution of instructions, pipelining and/or multithreading. Additionally or alternatively, the processor 202 may include one or more processors capable of processing large volumes of workloads and operations to provide support for big data analysis. In an example embodiment, the processor 202 may be in communication with the memory 204 via a bus for passing information among components of the system 102.

In an example, when the processor 202 is embodied as an executor of software instructions, the instructions may specifically configure the processor 202 to perform the algorithms and/or operations described herein when the instructions are executed. However, in some cases, the processor 202 may be a processor specific device (for example, a mobile terminal or a fixed computing device) configured to employ an embodiment of the present disclosure by further configuration of the processor 202 by instructions for performing the algorithms and/or operations described herein. The processor 202 may include, among other things, a clock, an arithmetic logic unit (ALU) and logic gates configured to support operation of the processor 202. The network environment, such as, 100 may be accessed using the communication interface 206 of the system 102. The communication interface 206 may provide an interface for accessing various features and data stored in the system 102.

For example, the memory 204 may be an electronic storage device (for example, a computer readable storage medium) comprising gates configured to store data (for example, bits) that may be retrievable by a machine (for example, a computing device like the processor 202). The memory 204 may be configured to store information, data, content, applications, instructions, or the like, for enabling the system 102 to conduct various functions in accordance with an example embodiment of the present disclosure. For example, the memory 204 may be configured to buffer input data for processing by the processor 202. The memory 204 may be configured to store instructions for execution by the processor 202.

The memory 204 of the system 102 may be configured to store a dataset (such as, but not limited to, map data, probe data, sensor data, historical magnetism data, generated magnetism data, measurement unit attributes, and navigation or routing instructions) associated with the geographical regions. In accordance with an embodiment, the memory 204 may include processing instructions for processing the historical magnetism data. The dataset may include real-time data and historical data relating to magnetic field in geographical regions.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

We claim:

1. A system comprising:
a memory configured to store computer executable instructions; and
one or more processors configured to execute the instructions to:
obtain a set of measurement unit attributes and location information associated with a measurement unit, the set of measurement unit attributes comprising a first magnetism data for the measurement unit;
identify a plurality of reference magnetism sources in proximity of the measurement unit, based on the location information;
obtain reference magnetism data from the plurality of reference magnetism sources;
and
generate second magnetism data for the measurement unit, based on the first magnetism data, the reference magnetism data, and a trained computational network.

2. The system of claim 1, wherein the one or more processors are further configured to:
obtain historical magnetism data for a plurality of geographical regions;
generate the first magnetism data for a first geographical region of the measurement unit based on the location information and the trained computational network, the trained machine-learning based computational network being trained on the historical magnetism data;
and
transmit the first magnetism data to the measurement unit, wherein the measurement unit generates the set of measurement unit attributes using the first magnetism data.

3. The system of claim 1, wherein the one or more processors are further configured to:
determine magnetism accuracy based on the reference magnetism data and the first magnetism data;
and
re-train the trained machine-learning based computational network based on the magnetism accuracy, the reference magnetism data, the set of measurement unit attributes and the first magnetism data.

4. The system of claim 3, wherein the one or more processors are further configured to:
generate the second magnetism data for the measurement unit, using the re-trained computational network;
transmit the second magnetism data to the measurement unit;
and
cause to generate, by the measurement unit, updated set of measurement unit attributes.

5. The system of claim 1, wherein the plurality of reference magnetism sources comprises one or more reference magnetic stations and one or more crowd data sources.

6. The system of claim 1, wherein the measurement unit is associated with at least one of: a vehicle, a compass, or an exploration system.

7. The system of claim 1, wherein the one or more processors are further configured to:
generate navigation instructions based on the second magnetism data;
and
update a map database based on the second magnetism data and the generated navigation instructions.

8. The system of claim 1, wherein the measurement unit is at least one of: a nine-axis inertial measurement unit, a six-axis inertial measurement unit, or a three-axis inertial measurement unit.

9. The system of claim 1, wherein the set of measurement unit attributes comprise at least one of: the first magnetism data, speed data, orientation data, force data, acceleration information, bearing information, and angular rate information.

10. The system of claim 1, wherein, to train the computation network, the one or more processors are further configured to:
receive training data comprising historical magnetism data for a plurality of geographical regions, the historical magnetism data comprising at least one of: one or more historical magnetometer readings, one or more crowd-sourced magnetometer readings, or one or more historical reference magnetism data;
determine a plurality of features corresponding to magnetism for each of the plurality of geographical regions, using the training data;
and
train the machine-learning based computational network to generate test magnetism value for one or more test geographical regions, using the plurality of features and the set of historical magnetism data.

11. A method comprising:
obtaining a set of measurement unit attributes and location information associated with a measurement unit, the set of measurement unit attributes comprising a first magnetism data for the measurement unit;
identifying a plurality of reference magnetism sources in proximity of the measurement unit, based on the location information;
obtaining reference magnetism data from the plurality of reference magnetism sources;
and
generating second magnetism data for the measurement unit, based on the first magnetism data, the reference magnetism data, and a trained computational network.

12. The method of claim 11, the method further comprising:
obtaining historical magnetism data for a plurality of geographical regions;
generating the first magnetism data for a first geographical region of the measurement unit based on the location information and the trained computational network, the trained machine-learning based computational network being trained on the historical magnetism data;
and
transmitting the first magnetism data to the measurement unit, wherein the measurement unit generates the set of measurement unit attributes using the first magnetism data.

13. The method of claim 11, the method further comprising:
determining magnetism accuracy based on the reference magnetism data and the first magnetism data;
and
re-training the trained machine-learning based computational network based on the magnetism accuracy, the reference magnetism data, the set of measurement unit attributes and the first magnetism data.

14. The method of claim 13, the method further comprising:
generating the second magnetism data for the measurement unit, using the re-trained computational network;
transmitting the second magnetism data to the measurement unit;
and
causing to generate, by the measurement unit, updated set of measurement unit attributes.

15. The method of claim 11, the method further comprising:
generating navigation instructions based on the second magnetism data;
and
updating a map database based on the second magnetism data and the generated navigation instructions.

16. The method of claim 11, wherein to train the computation network, the method further comprises:
receiving training data comprising historical magnetism data for a plurality of geographical regions, the historical magnetism data comprising at least one of: one or more historical magnetometer readings, one or more crowd-sourced magnetometer readings, or one or more historical reference magnetism data;
determining a plurality of features corresponding to magnetism for each of the plurality of geographical regions, using the training data;
and
training the machine-learning based computational network to generate test magnetism value for one or more test geographical regions, using the plurality of features and the set of historical magnetism data.

17. The method of claim 11, wherein the plurality of reference magnetism sources comprises one or more reference magnetic stations and one or more crowd data sources.

18. The method of claim 1, wherein the measurement unit is associated with at least one of: a vehicle, a compass, or an exploration system.

19. A computer programmable product comprising a non-transitory computer readable medium having stored thereon computer executable instructions, which when executed by one or more processors, cause the one or more processors to conduct operations comprising:
obtaining a set of measurement unit attributes and location information associated with a measurement unit, the set of measurement unit attributes comprising a first magnetism data for the measurement unit;
identifying a plurality of reference magnetism sources in proximity of the measurement unit, based on the location information;
obtaining reference magnetism data from the plurality of reference magnetism sources;
and
generating second magnetism data for the measurement unit, based on the first magnetism data, the reference magnetism data, and a trained computational network.

20. The computer programmable product of claim 18, the operations further comprising:
obtaining historical magnetism data for a plurality of geographical regions;
generating the first magnetism data for a first geographical region of the measurement unit based on the location information and the trained computational network, the trained machine-learning based computational network being trained on the historical magnetism data;
and
transmitting the first magnetism data to the measurement unit, wherein the measurement unit generates the set of measurement unit attributes using the first magnetism data.
